(19) United States
(12) Patent Application Publication
(10) Pub. No.: US 2015/0241519 A1
(43) Pub. Date: Aug. 27, 2015

(54) METHOD FOR MANAGING POWER OF ELECTRONIC DEVICE AND ELECTRONIC DEVICE THEREOF

(71) Applicant: Samsung Electronics Co., Ltd., Suwon-si (KR)

(72) Inventors: Eun-Kyoung LEE, Suwon-si (KR); Min-Su KIM, Suwon-si (KR); Se-Young JANG, Seongnam-si (KR); Seung-Chul CHOI, Suwon-si (KR)

(21) Appl. No.: 14/625,438

(22) Filed: Feb. 18, 2015

(30) Foreign Application Priority Data
Feb. 21, 2014 (KR) 10-2014-0020892

(51) Int. Cl. G01R 31/36

(52) U.S. Cl. CPC G01R 31/3648; G01R 31/3606

(57) ABSTRACT

A method for managing power of an electronic device and the electronic device thereof are provided. An operation method of the electronic device includes detecting a remaining battery capacity, calculating and storing a reduced ratio per unit time of the remaining battery capacity and, based on the reduced ratio, predicting a remaining operating time of the battery.

### CROSS-REFERENCE TO RELATED APPLICATION(S)

This application claims the benefit under 35 U.S.C. §119(a) of a Korean patent application filed on Feb. 21, 2014 in the Korean Intellectual Property Office and assigned Serial number 10-2014-0020892, the entire disclosure of which is hereby incorporated by reference.

### TECHNICAL FIELD

This present disclosure relates to a method for managing power of an electronic device and the electronic device thereof

### BACKGROUND

Electronic devices of various types such as smart phones, tablet Personal Computers (PCs) or the like can use Direct Current (DC) power that is supplied from a power adapter, or that is supplied from a battery. However, a battery has a limited capacity.

In the case of using battery power, the electronic device can display, for example, an indicator such as a stick or a bar corresponding to a battery's remaining capacity. If the remaining battery capacity becomes smaller than a preset reference, the electronic device can display various messages such as entering a power save mode or requesting an electric charge. Further, the electronic device can predict and display a remaining operating time based on the remaining battery capacity.

In the case of dividing a remaining battery capacity by a preset battery consumption rate to determine a remaining operating time, an inaccurate remaining operating time may be calculated because the preset battery consumption rate does not reflect the use pattern of a user who variously uses the electronic device.

The above information is presented as background information only to assist with an understanding of the present disclosure. No determination has been made, and no assertion is made, as to whether any of the above might be applicable as prior art with regard to the present disclosure.

### SUMMARY

Aspects of the present disclosure are to address at least the above-mentioned problems and/or disadvantages and to provide at least the advantages described below. Accordingly, an aspect of the present disclosure is to provide a method for managing power of an electronic device and the electronic device thereof, for accurately calculating a remaining operating time of a battery by, for example, reflecting a pattern of a user who variously uses the electronic device such as a smart phone, a tablet Personal Computer (PC), or the like.

Another aspect of the present disclosure is to provide a method for managing power of an electronic device and the electronic device thereof, for suitably controlling a display time point of a warning message such as discharge, charge, power saving, or the like by, for example, reflecting a pattern of a user who variously uses the electronic device such as a smart phone, a tablet PC, or the like.

In accordance with an aspect of the present disclosure, a method of operating an electronic device is provided. The method includes detecting a remaining battery capacity, calculating and storing a reduced ratio per unit time of the remaining battery capacity, and, based on the reduced ratio, predicting a remaining operating time of the battery.

In accordance with another aspect of the present disclosure, an electronic device is provided. The electronic device includes a detection unit configured to detect a remaining battery capacity, and a control unit configured to calculate and store a reduced ratio per unit time of the remaining battery capacity and, based on the reduced ratio, predict a remaining operating time of the battery.

Other aspects, advantages, and salient features of the disclosure will become apparent to those skilled in the art from the following detailed description, which, taken in conjunction with the annexed drawings, discloses various embodiments of the present disclosure.

### BRIEF DESCRIPTION OF THE DRAWINGS

The above and other objects, features, and advantages of certain embodiments of the present disclosure will be more apparent from the following description taken in conjunction with the accompanying drawings, in which:

FIG. 1 is a diagram illustrating a network environment including an electronic device according to an embodiment of the present disclosure;

FIG. 2 is a block diagram illustrating a construction of an electronic device according to an embodiment of the present disclosure;

FIG. 3 is a block diagram illustrating a partial construction of an electronic device according to an embodiment of the present disclosure;

FIG. 4 is a diagram illustrating a construction of State Of Charge (SOC) information according to an embodiment of the present disclosure;

FIG. 5 is a diagram illustrating a construction of remaining battery capacity information on an hourly basis for a one day period according to an embodiment of the present disclosure;

FIG. 6 is a diagram illustrating a construction of remaining battery capacity information on a daily basis for a one week period according to an embodiment of the present disclosure;

FIG. 7 is a diagram illustrating a construction of remaining battery capacity information on a daily basis for a one month period according to embodiment of the present disclosure;

FIG. 8 is a flowchart illustrating a method for managing power of an electronic device according to an embodiment of the present disclosure;

FIG. 9 is a diagram illustrating a process of updating a reduced ratio per unit hour of a remaining battery capacity according to a first embodiment of the present disclosure;

FIG. 10 is a diagram illustrating a process of updating a reduced ratio per unit hour of a remaining battery capacity according to a second embodiment of the present disclosure;

FIG. 11 is a diagram illustrating a process of updating a reduced ratio per unit hour of a remaining battery capacity according to a third embodiment of the present disclosure;

FIG. 12 is a diagram illustrating predicting a remaining operating time of a battery according to an embodiment of the present disclosure;

FIG. 13 is a diagram illustrating displaying a remaining operating time of a battery according to an embodiment of the present disclosure;

FIG. 14 is a flowchart illustrating a method for managing power of an electronic device according to an embodiment of the present disclosure;

FIG. 15 is a diagram illustrating applying a weight according to an embodiment of the present disclosure;

FIG. 16 is a diagram illustrating predicting a remaining operating time of a battery according to an embodiment of the present disclosure; and

FIG. 17 is a diagram illustrating predicting a remaining operating time of a battery according to an embodiment of the present disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the present disclosure. Accordingly, it should be apparent to those skilled in the art that the following description of various embodiments of the present disclosure is provided for illustration purpose only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

The expressions “comprise”, “may comprise” or the like as used in the various embodiments of the present disclosure indicate the existence of disclosed corresponding functions, operations, constituent elements or the like, and do not limit additional one or more functions, operations, constituent elements or the like. Also, it should be understood that the terms “comprise”, “have” or the like in the various embodiments of the present disclosure are to designate the existence of features stated in the specification, numerals, steps, operations, constituent elements, components, or a combination of them, and are not to previously exclude the possibility of existence or addition of one or more other features, numerals, steps, operations, constituent elements, components, or combinations of them.

The expressions such as “or” and the like in the various embodiments of the present disclosure include any and all combinations of words enumerated together. For example, “A or B” may include A, may include B, or may also include both A and B. The expressions such as “1st”, “2nd”, “first”, “second” or the like used in the various embodiments of the present disclosure may modify the various constituent elements of various embodiments, but are not intended to limit the corresponding constituent elements. For example, the expressions do not limit the order and/or importance and the like of the corresponding constituent elements. The expressions may be used to distinguish one constituent element from another constituent element. For example, both of a 1st user device and a 2nd user device are user devices, and represent different user devices. For example, a 1st constituent element may be named as a 2nd constituent element without departing from the scope of right of the various embodiments of the present disclosure. Likely, even a 2nd constituent element may be named as a 1st constituent element.

When it is mentioned that any constituent element is “coupled” or “connected” to another constituent element, it should be understood that the constituent element may be directly coupled or connected to the other constituent element or a third constituent element may also exist between the any constituent element and the other constituent element. In contrast, when it is mentioned that any constituent element is “directly coupled” or “directly connected” to another constituent element, it should be understood that a third constituent element does not exist between the any constituent element and the other constituent element.

The terms used in the various embodiments of the present disclosure are simply used for describing various embodiments, and are not intended to limit the various embodiments of the present disclosure. The expression of a singular number includes the expression of plural number unless the context clearly dictates otherwise. Unless defined otherwise, all the terms used herein including the technological or scientific terms have the same meaning as those commonly understood by a person having ordinary knowledge in the art to which various embodiments of the present disclosure belong. The terms as defined in a general dictionary should be interpreted as having the same meanings as the contextual meanings of a related technology, and are not interpreted as having ideal or excessively formal meanings unless defined clearly in various embodiments of the present disclosure.

An electronic device according to various embodiments of the present disclosure may be a device including a telecommunication function. For example, the electronic device may include at least one of a smart phone, a tablet Personal Computer (PC), a mobile phone, a video phone, an electronic book (e-book) reader, a desktop PC, a laptop PC, a netbook computer, a Personal Digital Assistant (PDA), a Portable Media Player (PMP), an MPEG Audio Layer 3 (MP3) player, a mobile medical instrument, a camera, or a wearable device (e.g., a Head Mounted Display (HMD) such as electronic glasses, electronic clothes, an electronic bracelet, an electronic necklace, an accessory, an electronic tattoo, or a smart watch).

According to various embodiments, the electronic device may be a smart electronic home appliance having a telecommunication function. The smart electronic home appliance may include, for example, at least one of a television, a Digital Versatile Disc (DVD) player, an audio system, a refrigerator, an air conditioner, a cleaner, an oven, a microwave, a washing machine, an air cleaner, a set-top box, a TV box (for example, Samsung HomeSync™, Apple TV™, or Google TV™), a game console, an electronic dictionary, an electronic locking system, a camcorder, or an electronic frame.

According to some embodiments, the electronic device may include at least one of various medical instruments (e.g., Magnetic Resonance Angiography (MRA), Magnetic Resonance Imaging (MRI), Computerized Tomography (CT), a moving-camera, an ultrasonic machine and the like), a navigation device, a Global Positioning System (GPS) receiver, an Event Data Recorder (EDR), a Flight Data Recorder (FDR), a car infotainment device, an electronic equipment for ship (e.g., a navigation device for ship, a gyrocompass and the like), avionics, a security instrument, a head unit for a car, an industrial or home robot, an Automatic Teller Machine (ATM) of a financial institute, or a Point Of Sales (POS) of a shop

According to various embodiments, the electronic device may include at least one of a part of furniture or building/structure including a telecommunication function, an electronic board, an electronic signature receiving device, a projector, or various metering instruments (e.g., tap water, electricity, gas, radio wave metering instrument or the like). The electronic device according to various embodiments of the present disclosure may be one of the aforementioned various devices or a combination of two or more. Also, the electronic device according to the various embodiments of the present disclosure may be a flexible device. Also, it is obvious to those skilled in the art that the electronic device according to the various embodiments of the present disclosure is not limited to the aforementioned instruments.

Below, an electronic device according to various embodiments of the present disclosure will be described with reference to the accompanying drawings. The term ‘user’ used in the various embodiments of the present disclosure may denote a person who uses the electronic device or a device (e.g., an artificial intelligent electronic device) which uses the electronic device.

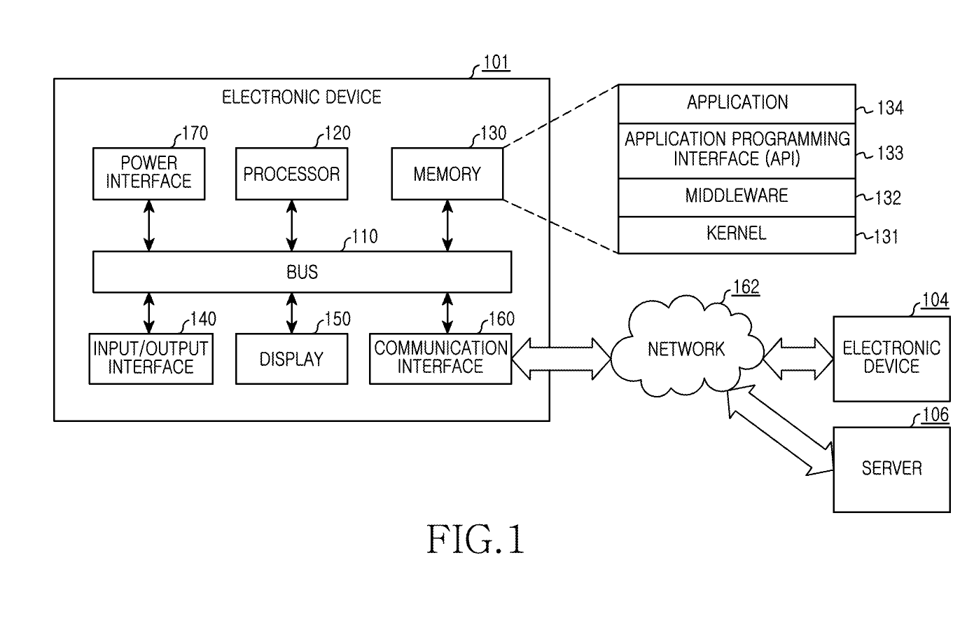

FIG. 1 is a diagram illustrating a network environment including an electronic device according to an embodiment of the present disclosure.

Referring to FIG. 1, the electronic device 101 may include a bus 110, a processor 120, a memory 130, an input/output interface 140, a display 150, a communication interface 160, a power interface 170 and the like.

The processor 120 may, for example, receive instructions from the aforementioned other constituent elements (e.g., the memory 130, the input/output interface 140, the display 150, the communication interface 160, and the like) through the bus 110, decipher the received instructions, and execute operation or data processing according to the deciphered instructions.

The memory 130 may store an instruction or data that is received from the processor 120 or the other constituent elements (e.g., the input/output interface 140, the display 150, the communication interface 160, the power interface 170 or the like) or is generated by the processor 120 or the other constituent elements. The memory 130 may, for example, include programming modules such as a kernel 131, a middleware 132, an Application Programming Interface (API) 133, an application 134 or the like. The aforementioned programming modules each may be comprised of software, firmware, hardware or a combination of at least two or more of them.

The kernel 131 may control or manage system resources (e.g., the bus 110, the processor 120, the memory 130 or the like) used for executing operations or functions implemented by the other programming modules, for example, the middleware 132, the API 133, or the application 134. Also, the kernel 131 may provide an interface enabling the middleware 132, the API 133, or the application 134 to connect and control or manage the individual constituent element of the electronic device 101.

The middleware 132 may perform a relay role of enabling the API 133 or the application 134 to communicate and exchange data with the kernel 131. Also, in relation to work requests received from the applications 134, the middleware 132 may, for example, perform control (e.g., scheduling, load balancing, etc.) over the work requests using a method of allocating at least one application among the applications 134 priority order capable of using the system resources (e.g., the bus 110, the processor 120, the memory 130 or the like) of the electronic device 101.

The API 133 is an interface enabling the application 134 to control a function provided by the kernel 131 or the middleware 132. The API 133 may, for example, include at least one interface or function (e.g., instruction) for file control, window control, picture processing, character control or the like.

According to various embodiments, the application 134 may include a Short Message Service (SMS)/Multimedia Message Service (MMS) application, an electronic mail (e-mail) application, a calendar application, an alarm application, a health care application (e.g., an application measuring momentum, blood sugar or the like), an environment information application (e.g., an application providing air pressure, humidity, temperature information or the like) or the like. Additionally or alternatively, the application 134 may be an application related with information exchange between the electronic device 101 and an external electronic device (e.g., an electronic device 104). The application related with the information exchange may include, for example, a notification relay application for relaying specific information to the external electronic device, or a device management application for managing the external electronic device.

For example, the notification relay application may include a function of relaying to the external electronic device (e.g., the electronic device 104) notification information generated in other applications (e.g., the SMS/MMS application, the e-mail application, the health care application, the environment information application or the like) of the electronic device 101. Additionally or alternatively, the notification relay application may, for example, receive notification information from the external electronic device (e.g., the electronic device 104) and provide the received notification information to a user. The device management application may, for example, manage (e.g., install, delete or update) a function (e.g., turn-on/turn-off of the external electronic device itself (or some constituent components), or adjustment of a brightness (or resolution) of a display) of at least a part of the external electronic device (e.g., the electronic device 104) communicating with the electronic device 101, an application operating in the external electronic device, or a service (e.g., a call service or a message service) provided in the external electronic device.

According to various embodiments, the application 134 may include an application designated according to an attribute (e.g., the kind of electronic device) of the external electronic device (e.g., the electronic device 104). For example, when the external electronic device is an MP3 player, the application 134 may include an application related with music playback. Similarly, when the external electronic device is a mobile medical instrument, the application 134 may include an application related with health care. According to an embodiment, the application 134 may include at least one of an application designated to the electronic device 101 or an application received from the external electronic device (e.g., a server 106 or the electronic device 104).

The input/output interface 140 may forward an instruction or data, which is inputted from a user through an input/output device (e.g., a sensor, a keyboard or a touch screen), for example, to the processor 120, the memory 130, the communication interface 160, or the power interface 170 through the bus 110. For example, the input/output interface 140 may provide data about a user's touch inputted through the touch screen, to the processor 120. Also, the input/output interface 140 may, for example, output through the input/output device (e.g., a speaker or a display) an instruction or data which is received from the processor 120, the memory 130, the communication interface 160, or the power interface 170 through the bus 110. For example, the input/output interface 140 may output voice data, which is processed through the processor 120, to the user through the speaker.

The display 150 may display a variety of information (e.g., multimedia data, text data, or the like) to a user. The communication interface 160 may establish communication between the electronic device 101 and the external device (e.g., the electronic device 104 or server 106). For example, the communication interface 160 may be coupled to a network 162 through wireless communication or wired communication and communicate with the external device. The wireless communication may, for example, include at least one of WiFi, Bluetooth (BT), Near Field Communication (NFC), Global Positioning System (GPS) or cellular communication (e.g., Long Term Evolution (LTE), LTE-Advanced (LTE-A), Code Division Multiple Access (CDMA), Wireless CDMA (WCDMA), Universal Mobile Telecommunication System (UMTS), Wireless Broadband (WiBro), Global System for Mobile Communications (GSM), or the like). The wired communication may, for example, include at least one of a Universe Serial Bus (USB), a High Definition Multimedia Interface (HDMI), a Recommended Standard-232 (RS-232), or a Plain Old Telephone System (POTS).

According to an embodiment, the network 162 may be a telecommunication network. The telecommunication network may include at least one of a computer network, the Internet, the Internet of things or a telephone network. According to an embodiment, a protocol (e.g., a transport layer protocol, a data link layer protocol or a physical layer protocol) for communication between the electronic device 101 and the external device may be supported in at least one of the application 134, the application programming interface 133, the middleware 132, the kernel 131, or the communication interface 160.

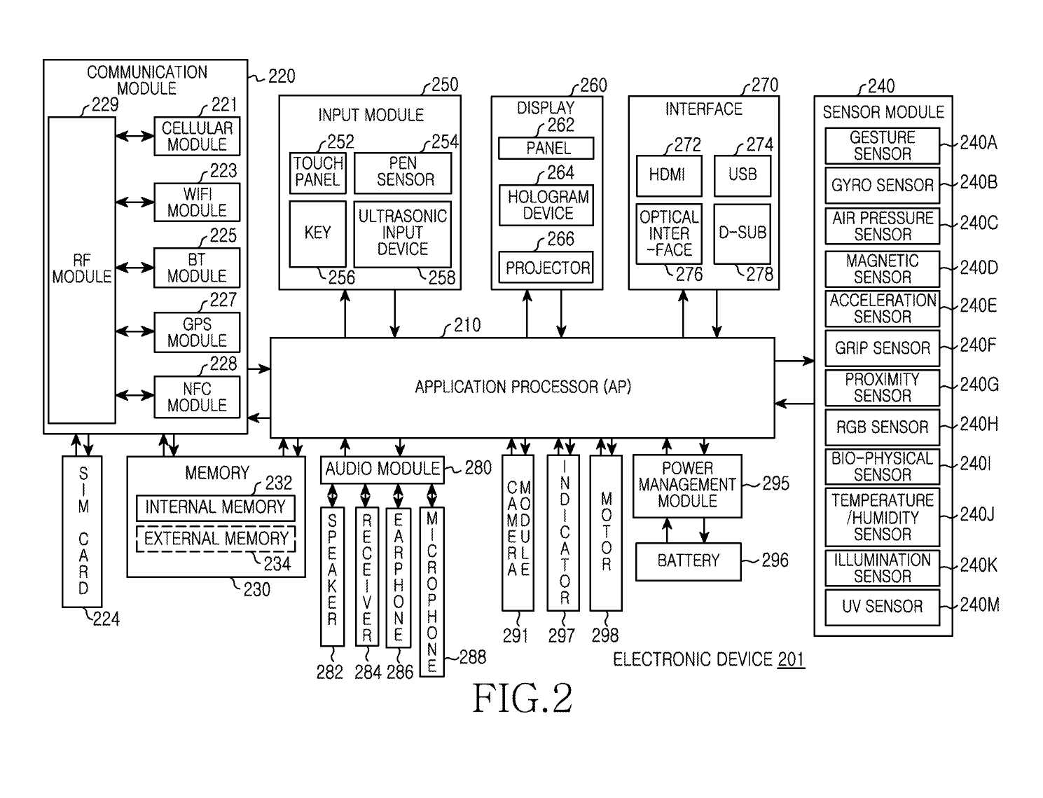

FIG. 2 is a block diagram illustrating a construction of an electronic device according to an embodiment of the present disclosure.

Referring to FIG. 2, the electronic device 201 may include one or more Application Processors (APs) 210, a communication module 220, a Subscriber Identification Module (SIM) card 224, a memory 230, a sensor module 240, an input device 250, a display 260, an interface 270, an audio module 280, a camera module 291, a power management module 295, a battery 296, an indicator 297, and a motor 298.

The AP 210 may drive an operating system or an application program and control a plurality of hardware or software constituent elements coupled to the AP 210, and perform processing and operations of various data including multimedia data. The AP 210 may be, for example, implemented as a System on Chip (SoC). According to an embodiment, the AP 210 may further include a Graphic Processing Unit (GPU) (not shown).

The communication module 220 (e.g., the communication interface 160) may perform data transmission/reception in communication between other electronic devices (e.g., the electronic device 104 or the server 106) coupled with the electronic device 201 (e.g., the electronic device 101) through a network. According to an embodiment, the communication module 220 may include a cellular module 221, a WiFi module 223, a BT module 225, a GPS module 227, an NFC module 228, and a Radio Frequency (RF) module 229.

The cellular module 221 may provide voice telephony, video telephony, a text service, an Internet service or the like through a communication network (e.g., LTE, LTE-A, CDMA, WCDMA, UMTS, WiBro, GSM or the like). Also, the cellular module 221 may, for example, perform electronic device distinction and authorization within a communication network using a subscriber identification module (e.g., the SIM card 224). According to an embodiment, the cellular module 221 may perform at least some functions among functions that the AP 210 may provide. For example, the cellular module 221 may perform at least a part of a multimedia control function.

According to an embodiment, the cellular module 221 may include a Communication Processor (CP). Also, the cellular module 221 may be, for example, implemented as a SoC. In FIG. 2, the constituent elements such as the cellular module 221 (e.g., the communication processor), the memory 230, the power management module 295 or the like are illustrated as constituent elements separate from the AP 210. However, according to an embodiment, the AP 210 may be implemented to include at least some (e.g., the cellular module 221) of the aforementioned constituent elements.

According to an embodiment, the AP 210 or the cellular module 221 (e.g., the communication processor) may load to a volatile memory an instruction or data received from a nonvolatile memory coupled to each of the AP 210 and the cellular module 221 or at least one of other constituent elements, and process the loaded instruction or data. Also, the AP 210 or the cellular module 221 may store data received from at least one other constituent elements or generated in at least one of the other constituent elements, in the nonvolatile memory.

The WiFi module 223, the BT module 225, the GPS module 227, or the NFC module 228 may each include a processor for processing data transmitted/received through the corresponding module, for example. In FIG. 2, each of the cellular module 221, the WiFi module 223, the BT module 225, the GPS module 227 or the NFC module 228 is illustrated as a separate block. But, according to various embodiments, at least some (e.g., two or more) of the cellular module 221, the WiFi module 223, the BT module 225, the GPS module 227 or the NFC module 228 may be included within one Integrated Circuit (IC) or IC package. For example, at least some (e.g., a communication processor corresponding to the cellular module 221 and a WiFi processor corresponding to the WiFi module 223) of the processors corresponding to the cellular module 221, the WiFi module 223, the BT module 225, the GPS module 227 or the NFC module 228 may be implemented as one SoC.

The RF module 229 may perform data transmission/reception, for example, RF signal transmission/reception. The RF module 229 may include, though not illustrated, a transceiver, a Power Amplifier Module (PAM), a frequency filter, a Low Noise Amplifier (LNA) or the like, for example. Also, the RF module 229 may further include components, for example, a conductor, a conductive line or the like for transmitting/receiving an electromagnetic wave on a free space in wireless communication. In FIG. 2, it is illustrated that the cellular module 221, the WiFi module 223, the BT module 225, the GPS module 227, and the NFC module 228 share one RF module 229 with each other. But, according to an embodiment, at least one of the cellular module 221, the WiFi module 223, the BT module 225, the GPS module 227, or the NFC module 228 may perform RF signal transmission/reception through a separate RF module.

The SIM card 224 may be a card including a subscriber identification module, and may be inserted into a slot provided in a specific position of the electronic device 201. The SIM card 224 may include unique identification information (e.g., an Integrated Circuit Card ID (ICCID)) or subscriber information (e.g., an International Mobile Subscriber Identity (IMSI)).

The memory 230 (e.g., the memory 130) may include an internal memory 232 or an external memory 234. The internal memory 232 may, for example, include at least one of a volatile memory (e.g., a Dynamic Random Access Memory (DRAM), a Static RAM (SRAM), a Synchronous Dynamic RAM (SDRAM) and the like) or a nonvolatile memory (e.g., a One-Time Programmable Read Only Memory (OTPROM), a Programmable ROM (PROM), an Erasable and Programmable ROM (EPROM), an Electrically Erasable and Programmable ROM (EEPROM), a mask ROM, a flash ROM, a Not AND (NAND) flash memory, a Not OR (NOR) flash memory and the like).

According to an embodiment, the internal memory 232 may be a Solid State Drive (SSD). The external memory 234 may further include a flash drive, for example, a Compact Flash (CF), a Secure Digital (SD), a micro-SD, Mini-SD, an extreme Digital (xD), a memory stick or the like. The external memory 234 may be functionally coupled with the electronic device 201 through various interfaces. According to an embodiment, the electronic device 201 may further include a storage device (or storage media) such as a hard drive.

The sensor module 240 may measure a physical quantity or sense an activation state of the electronic device 201, and convert measured or sensed information into an electric signal. The sensor module 240 may, for example, include at least one of a gesture sensor 240A, a gyro sensor 240B, an air pressure sensor 240C, a magnetic sensor 240D, an acceleration sensor 240E, a grip sensor 240F, a proximity sensor 240G, a color sensor 240H (e.g., a Red, Green, Blue (RGB) sensor), a bio-physical sensor 2401, a temperature/humidity sensor 240J, an illumination sensor 240K, or a Ultraviolet (UV) sensor 240M. Additionally or alternatively, the sensor module 240 may, for example, include an E-nose sensor (not shown), an Electromyography (EMG) sensor (not shown), an Electroencephalogram (EEG) sensor (not shown), an Electrocardiogram (ECG) sensor (not shown), an Infrared (IR) sensor (not shown), an iris sensor (not shown), a fingerprint sensor (not shown) or the like. The sensor module 240 may further include a control circuit for controlling at least one or more sensors belonging therein.

The input device 250 may include a touch panel 252, a (digital) pen sensor 254, a key 256, or an ultrasonic input device 258. The touch panel 252 may, for example, recognize a touch input in at least one method among a capacitive overlay method, a pressure sensitive method, an infrared beam method, or an acoustic wave method. Also, the touch panel 252 may also further include a control circuit. In the capacitive overlay method, physical contact or proximity recognition is possible. The touch panel 252 may also further include a tactile layer. In this case, the touch panel 252 may provide a tactile response to a user.

The (digital) pen sensor 254 may be, for example, implemented using a method being the same or similar to a method of receiving a user's touch input or a separate sheet for detection. The key 256 may, for example, include a physical button, an optical key, or a keypad. The ultrasonic input device 258 is a device capable of checking data by sensing a sound wave with a microphone (e.g., a microphone 288) of the electronic device 201 through an input tool generating an ultrasonic signal. The ultrasonic input device 258 is possible to perform wireless detection. According to an embodiment, by using the communication module 220, the electronic device 201 may also receive a user input from an exterior device (e.g., a computer or a server) coupled with the communication module 220.

The display 260 (e.g., the display 150) may include a panel 262, a hologram device 264, or a projector 266. The panel 262 may be, for example, a Liquid Crystal Display (LCD), an Active-Matrix Organic Light-Emitting Diode (AMOLED) or the like. The panel 262 may be, for example, implemented to be flexible, transparent, or wearable. The panel 262 may be also constructed together with the touch panel 252 as one module. The hologram device 264 may show a three-dimensional image in the air using interference of light. The projector 266 may display a video by projecting light to a screen. The screen may be, for example, located inside or outside the electronic device 201. According to an embodiment, the display 260 may further include a control circuit for controlling the panel 262, the hologram device 264, and the projector 266.

The interface 270 may, for example, include an HDMI 272, a USB 274, an optical interface 276, or a D-subminiature (D-sub) 278. The interface 270 may be, for example, included in the communication interface 160 illustrated in FIG. 1. Additionally or alternatively, the interface 270 may, for example, include a Mobile High-definition Link (MHL) interface, a Secure Digital/Multi Media Card (SD/MMC) interface, or an Infrared Data Association (IrDA) standard interface.

The audio module 280 may convert sound and an electric signal interactively. At least some constituent elements of the audio module 280 may be, for example, included in the input/output interface 140 illustrated in FIG. 1. The audio module 280 may process sound information inputted or outputted through a speaker 282, a receiver 284, an earphone 286, the microphone 288, or the like, for example. The camera module 291 is a device capable of taking a still picture and a moving picture. According to an embodiment, the camera module 291 may include one or more image sensors (e.g., a front sensor or rear sensor), a lens (not shown), an Image Signal Processor (ISP) (not shown), or a flash (not shown) (e.g., an LED or a xenon lamp).

The power management module 295 may manage electric power of the electronic device 201. Also, the power management module 295 may include, for example, a Power Management Integrated Circuit (PMIC), a charger Integrated Circuit (IC), or a battery or fuel gauge. The PMIC may be, for example, mounted within an integrated circuit or an SoC semiconductor. A charging method may be divided into wired and wireless charging methods. The charger IC may charge a battery, and may prevent the introduction of overvoltage or overcurrent from an electric charger.

According to an embodiment, the charger IC may include a charger IC of at least one of the wired charging method or the wireless charging method. As the wireless charging method, there are, for example, a magnetic resonance method, a magnetic induction method, an electromagnetic wave method or the like. Supplementary circuits for wireless charging, for example, circuits such as a coil loop, a resonance circuit, a rectifier or the like may be added.

A battery fuel gauge may, for example, measure a level of the battery 296, a voltage during charging, an electric current, a temperature, etc. The battery 296 may store or generate electricity, and may supply power to the electronic device 201 using the stored or generated electricity. The battery 296 may, for example, include a rechargeable battery, a solar battery, etc.

The indicator 297 may display a specific state of the electronic device 201 or part (e.g., the AP 210) thereof, for example, a booting state, a message state, a charging state or the like. The motor 298 may convert an electric signal into a mechanical vibration. Though not illustrated, the electronic device 201 may include a processing device (e.g., a GPU) for mobile TV support. The processing device for mobile TV support may process media data according to the standards of Digital Multimedia Broadcasting (DMB), Digital Video Broadcasting (DVB), a media flow or the like, for example.

The aforementioned constituent elements of an electronic device according to various embodiments of the present disclosure may be each comprised of one or more components, and a name of the corresponding constituent element may be different according to the kind of the electronic device. An electronic device according to various embodiments of the present disclosure may include at least one of the aforementioned constituent elements, and may omit some constituent elements or further include additional other constituent elements. Also, some of the constituent elements of an electronic device according to various embodiments of the present disclosure are combined and constructed as one entity, thereby being able to identically perform the functions of the corresponding constituent elements before combination.

A method for managing power of an electronic device and the electronic device thereof according to various embodiments of the present disclosure are described below.

The electronic device according to various embodiments of the present disclosure may be an electronic device of various types such as a smart phone, a tablet PC, or the like, and may include constituent elements illustrated in FIG. 1 and FIG. 2. Further, the electronic device may reflect a pattern of a user who variously uses several functions of the electronic device, thereby predicting a remaining operating time of the battery, and may suitably control a display time point of a warning message such as discharge, charge, power saving and the like.

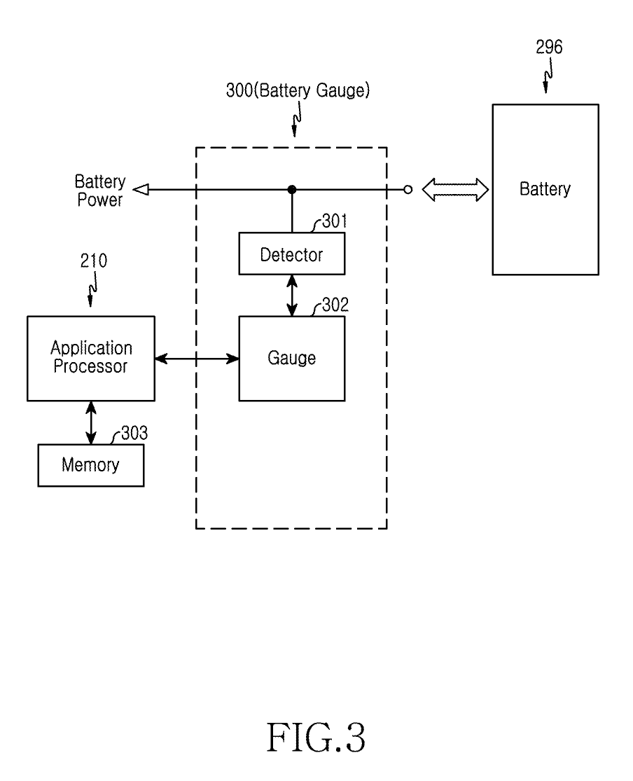

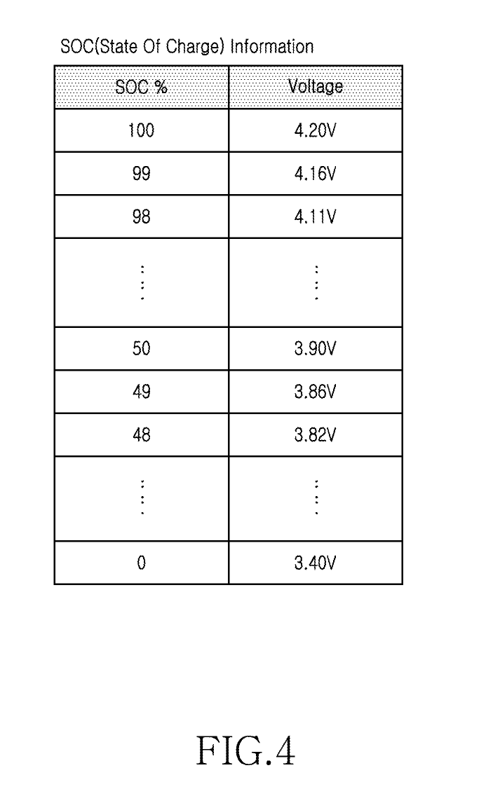

FIG. 3 is a block diagram illustrating a partial construction of an electronic device according to an embodiment of the present disclosure. FIG. 4 is a diagram illustrating a construction of State Of Charge (SOC) information according to an embodiment of the present disclosure,

Referring to FIG. 3, a battery gauge 300 included in the electronic device may include a detector 301 for detecting a charging or discharging voltage and the like of the battery 296, a gauge 302 for detecting a remaining battery capacity corresponding to the detected voltage, and the like.

The application processor 210 included in the electronic device may compare a voltage value detected by the battery gauge 300 with State Of Charge (SOC) information stored in a memory 303. The memory 303 may be an internal memory of the application processor 210 or an external memory.

Referring to FIG. 4, the SOC information may be stored in a list form and include SOC % values ranging from an SOC 100% value indicating a charged state of a battery to an SOC 0% value indicating a discharged state of the battery.

Each battery voltage value detected by the battery gauge 300 may be stored with a matching SOC % value of the SOC information stored in the memory. For example, the SOC 100% value may be matched with a battery voltage value of 4.20 V, and the SOC 0% value may be matched with a battery voltage value of 3.40 V. The SOC information may be provided and stored by a battery manufacturing company, or may be previously stored as a result value of an earlier implemented experiment.

The battery gauge 300 detects a voltage value corresponding to a remaining battery capacity at a desired frequency for a desired duration. For example, the battery gauge 300 may detect a voltage value corresponding to a remaining battery capacity every hour for a 24 hour period. The application processor 210 compares the detected voltage value with the SOC information of the memory 303 and reads from the SOC information an SOC % value matching the detected voltage value corresponding to the remaining battery capacity. Based on the SOC % value read from the SOC information, the application processor 210 calculates and stores a reduced ratio per unit hour of the remaining battery capacity, and predicts a remaining operating time of the battery based on the calculated reduced ratio.

The reduced ratio may be stored by frequency or period (e.g., hour) within remaining battery capacity information on a daily basis. The battery gauge 300 may be called a detection unit for detecting a remaining battery capacity and the like. The application processor 210 may be variously called a control unit and the like for calculating, accumulating and storing a reduced ratio per unit hour of a remaining battery capacity, and predicting a remaining operating time of the battery based on the reduced ratio.

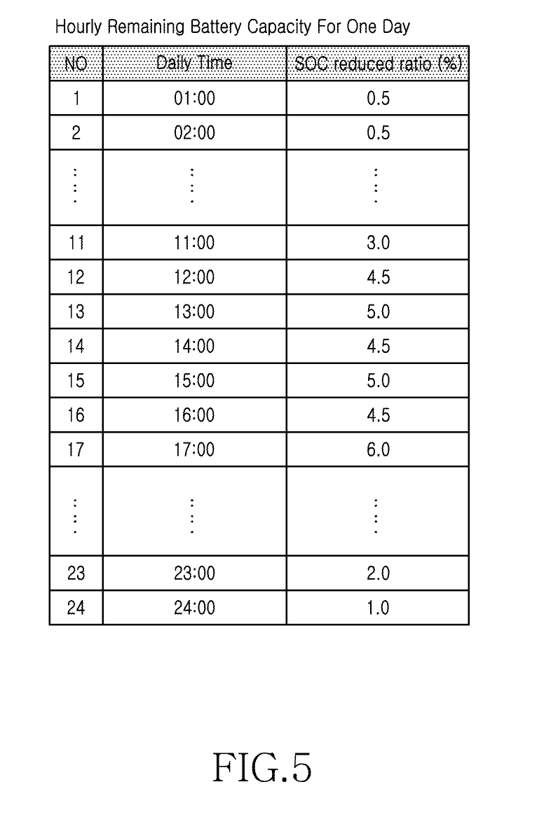

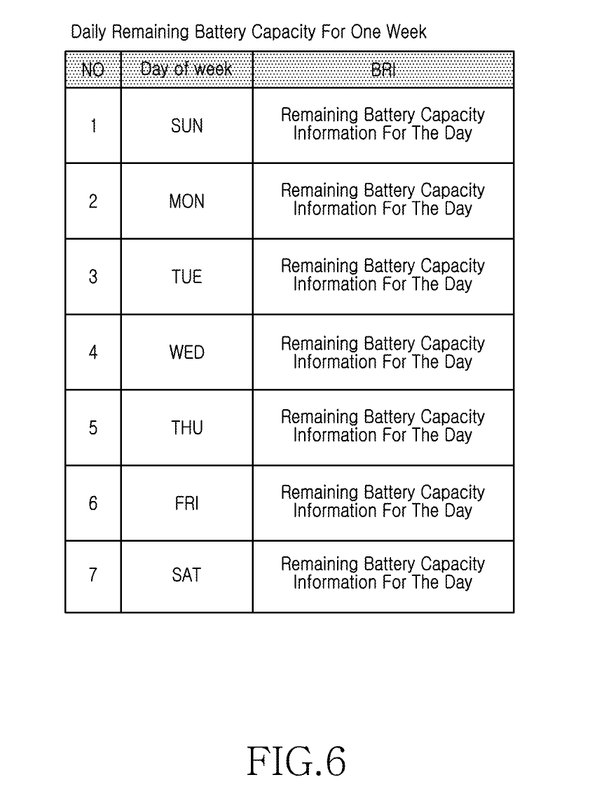

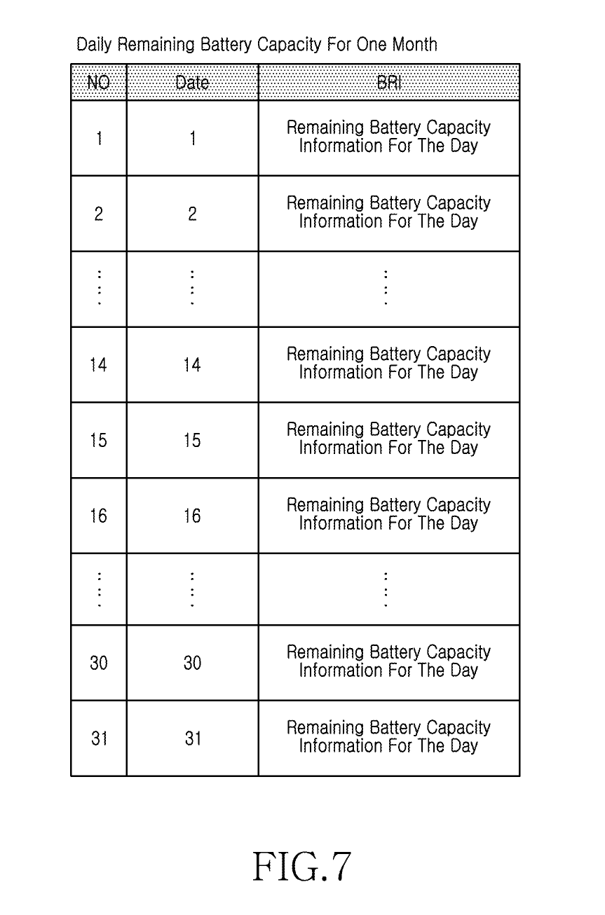

FIG. 5 is a diagram illustrating a construction of remaining battery capacity information on an hourly basis for a one day period according to an embodiment of the present disclosure. FIG. 6 is a diagram illustrating a construction of remaining battery capacity information on a daily basis for a one week period according to an embodiment of the present disclosure. FIG. 7 is a diagram illustrating a construction of remaining battery capacity information on a daily basis for a one month period according to embodiment of the present disclosure.

Referring to FIG. 5, a reduced ratio of a remaining battery capacity per unit hour of a preset constant period may be stored in a list form within the remaining battery capacity information. For example, if the unit hour is set as one hour, an SOC reduced ratio dependent on remaining battery capacity reduction calculated at 1-hour intervals from 01:00 to 24:00 may be stored as hourly remaining battery capacity information.

The battery gauge 300 detects a voltage value corresponding to a remaining battery capacity. The application processor 210 searches for an SOC % value matching with or otherwise corresponding to the detected voltage value in the SOC information of the memory 303, calculates, based on the searched SOC % value, an SOC reduced ratio dependent on remaining battery capacity reduction per unit hour, and stores the calculated SOC reduced ratio. For example, if an SOC % value of 14:00 is less than an SOC % value of 13:00 by 5%, the application processor 210 stores 5% as an SOC reduced ratio of 13:00 and, if an SOC % value of 15:00 is less than an SOC % value of 14:00 by 4.5%, the application processor 210 stores 4.5% as an SOC reduced ratio of 14:00.

The unit hour may be changed from an arbitrary unit hour, for example, 1 hour, to 2 hours, or may be changed from 1 hour to 30 minutes by a user's selection. Further, the unit hour may be also changed into an arbitrary time interval by occurrence of an event regarding the remaining battery capacity. For example, the unit hour may be decreased from 1 hour to 30 minutes for a time zone (e.g., 18:00 to 20:00) in which a battery consumption amount is suddenly increased. As another example, the unit hour may be increased from 1 hour to 2 hours for a time zone (e.g., 24:00 to 06:00) in which the battery consumption amount is extremely small.

The application processor 210 may also accumulate and manage an SOC reduced ratio dependent on remaining battery capacity reduction per unit hour, as remaining battery capacity information on a weekly basis or remaining battery capacity information on a monthly basis. For example, as illustrated in FIG. 6, the daily remaining battery capacity information for one week may store remaining battery capacity information for each day of the week ranging from Sunday to Saturday. As illustrated in FIG. 7, the daily remaining battery capacity information for one month may store remaining battery capacity information for each date ranging from day 1 to maximum day 31.

The application processor 210 may analyze the daily remaining battery capacity information for one week and extract a specific day of the week on which a battery consumption amount is large. Further, the application processor 210 may analyze the daily remaining battery capacity information for one month and extract a specific date on which the battery consumption amount is large.

When predicting a remaining operating time of the battery on the extracted specific day of the week or on the extracted specific date, the application processor 210 may also assign a weight of a relatively larger battery consumption amount than those of the other days of the week or the other dates, and predict that the remaining operating time of the battery will be short, thereby reflecting a unique pattern of a user who uses the electronic device more on the specific day of the week or on the specific date.

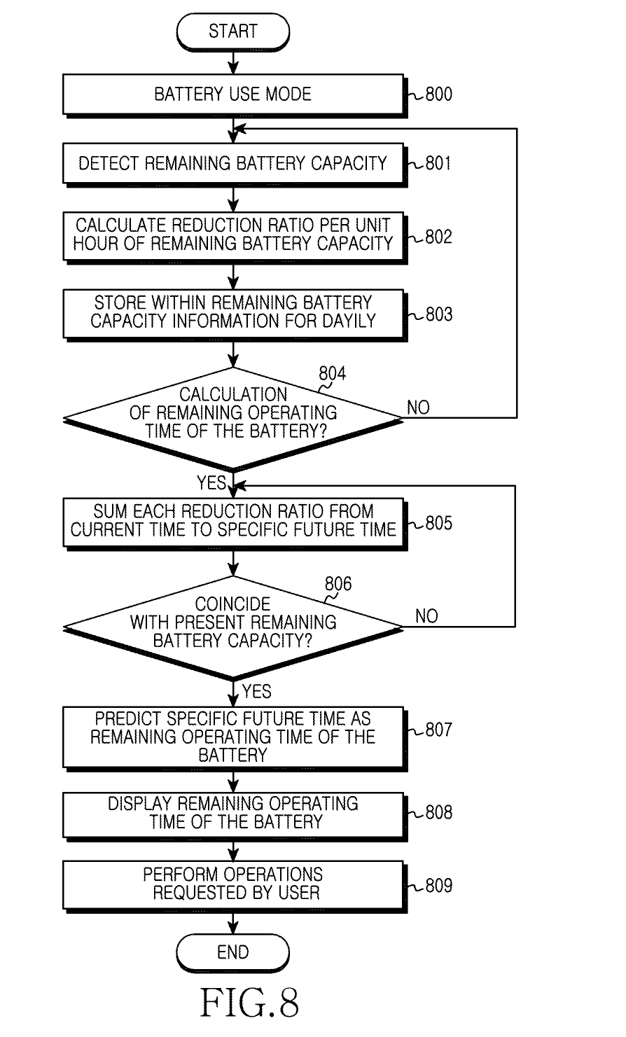

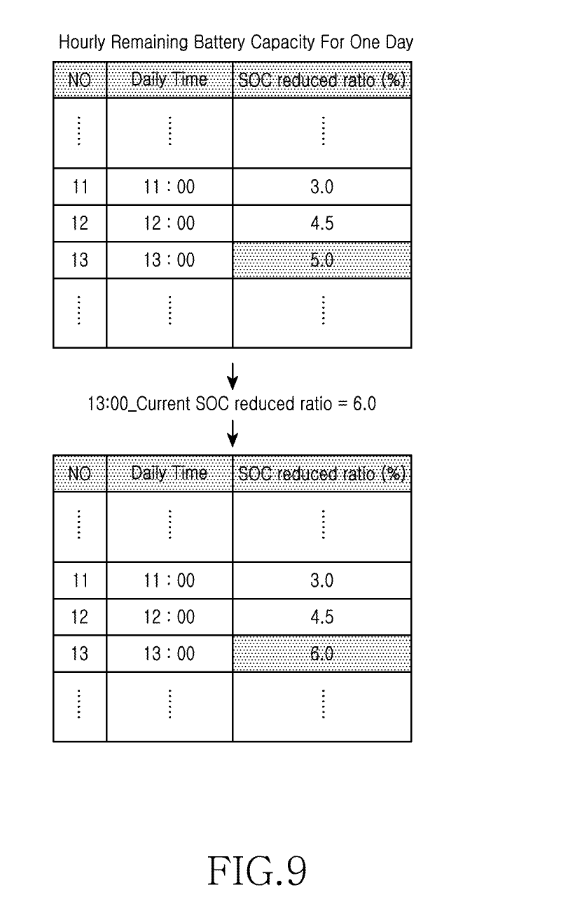

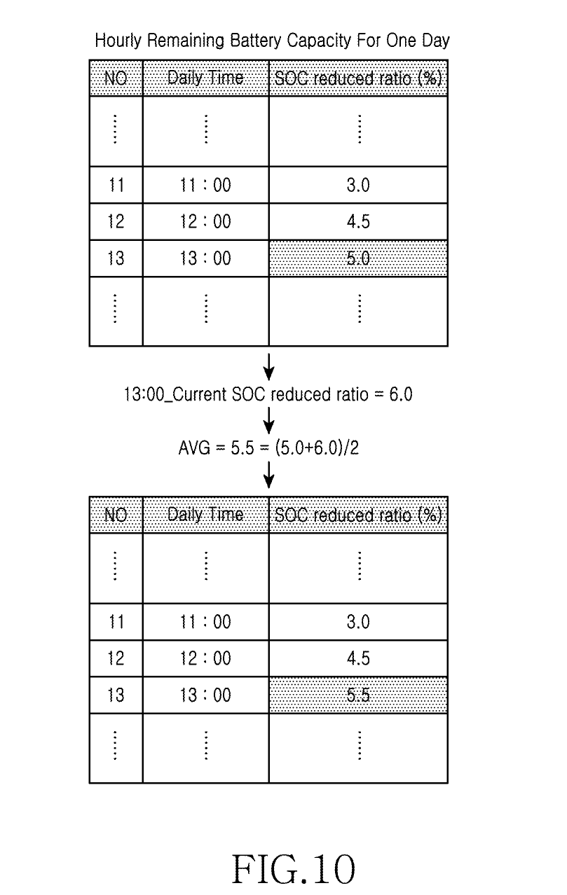

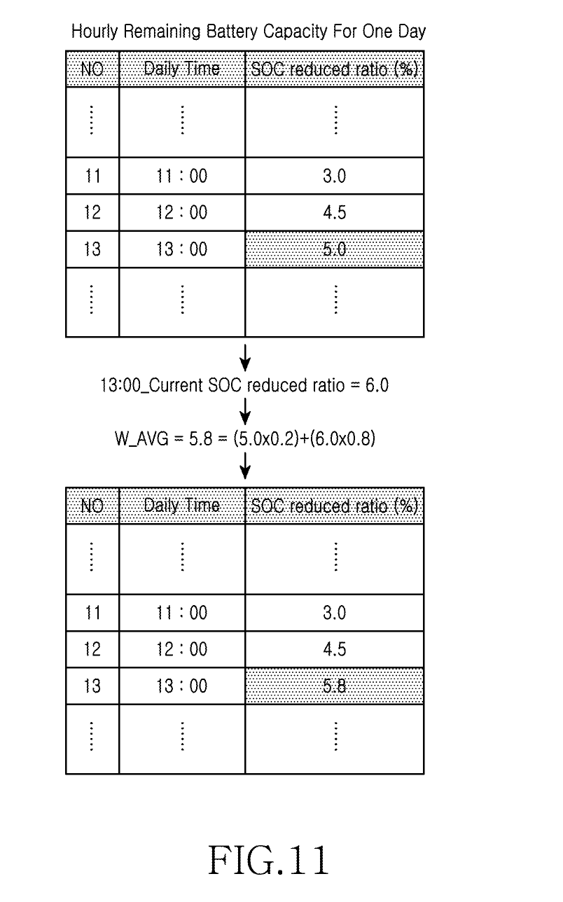

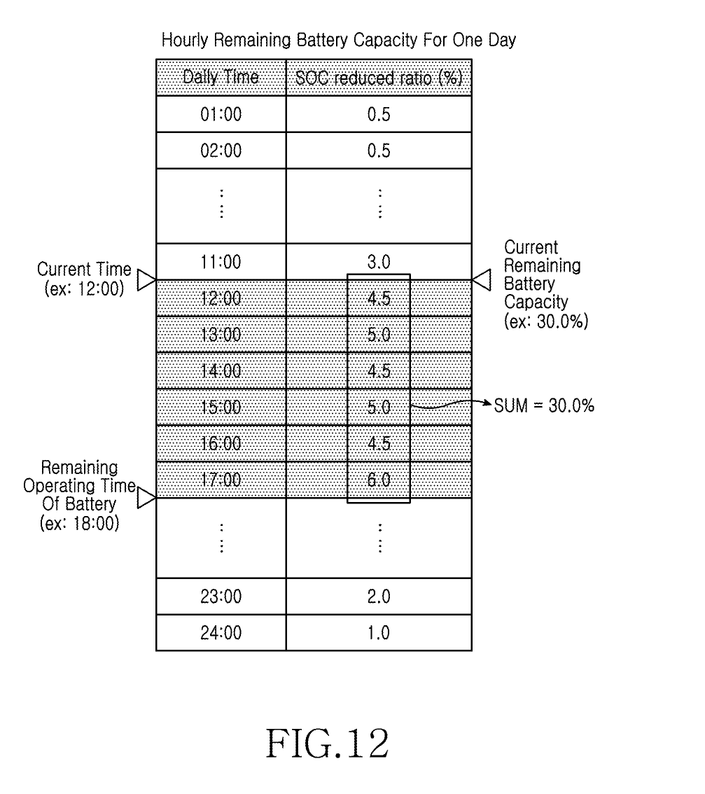

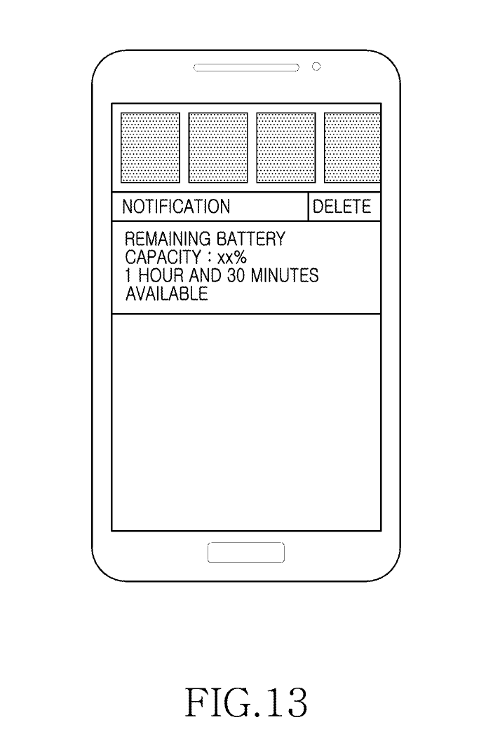

FIG. 8 is a flowchart illustrating an operation for managing power of an electronic device according to an embodiment of the present disclosure. FIG. 9 is a diagram illustrating a process of updating a reduced ratio per unit hour of a remaining battery capacity according to a first embodiment of the present disclosure. FIG. 10 is a diagram illustrating a process of updating a reduced ratio per unit hour of a remaining battery capacity according to a second embodiment of the present disclosure. FIG. 11 is a diagram illustrating a process of updating a reduced ratio per unit hour of a remaining battery capacity according to a third embodiment of the present disclosure. FIG. 12 is a diagram illustrating predicting a remaining operating time of a battery according to an embodiment of the present disclosure. FIG. 13 is a diagram illustrating displaying a remaining operating time of a battery according to an embodiment of the present disclosure.

Referring to FIG. 8, a present power mode is a battery use mode in operation 800. In operation 801, the application processor 210 controls the battery gauge 300 to detect a remaining battery capacity at a certain frequency for a certain duration. For example, the application processor 210 may control the battery gauge to detect remaining battery capacity at a frequency of every hour for a period of 24 hours.

In operation 802, the application processor 210 calculates a reduced ratio per unit hour of the remaining battery capacity. As an example, the application processor 210 calculates a reduced ratio per unit hour of the remaining battery capacity by searching the memory 303 for an SOC % value matching with or otherwise corresponding to a voltage value detected by the battery gauge 300 and calculating a difference value between the searched SOC % value and an SOC % value already searched at an earlier unit hour. For example, if an SOC % value of 14:00 is less than an SOC % value of 13:00 by 6%, the application processor 210 may calculate an SOC 6% as a reduced ratio of the remaining battery capacity which is reduced during 1 hour from 13:00 to 14:00.

In operation 803, the application processor 210 stores the calculated reduced ratio SOC 6% dependent on the remaining battery capacity reduction, within hourly remaining battery capacity information for one day. For example, as illustrated in FIG. 9, assuming that an SOC 5% matching with 13:00 has been already stored within the hourly remaining battery capacity information for one day, the application processor 210 may update the SOC 5% into the newly calculated SOC 6% value, and store the newly calculated SOC 6% value matching with 13:00 within the hourly remaining battery capacity information for one day.

In another embodiment, the application processor 210 may update and store an average value of a value of summing a previously stored reduced ratio and a currently calculated reduced ratio. For example, as illustrated in FIG. 10, assuming that an SOC 5% matching with a unit hour 13:00 has been already stored within the hourly remaining battery capacity information for a day and a newly calculated reduced ratio is an SOC 6% value, the application processor 210 may update the SOC 5% into an average value SOC 5.5% of a sum of the SOC 5% and the SOC 6%, and store the SOC 5.5% matching with the unit hour 13:00 within the hourly remaining battery capacity information for one day.

Further, the application processor 210 may update a previously stored reduced ratio into a value by multiplying the previously stored reduced ratio by a 1^{st} weight (M) and a currently calculated reduced ratio by a 2^{nd} weight (N, N>M, N+M=1) respectively and then summing the multiplication results. The application processor 210 may store the updated value within the hourly remaining battery capacity information for one day. For example, as illustrated in FIG. 11, assuming that an SOC 5% matching with a unit hour 13:00 has been already stored and a newly calculated reduced ratio is an SOC 6% value, the application processor 210 may update the SOC 5% into an SOC 5.8% value of multiplying the SOC 5% by 0.2 and multiplying the SOC 6% by 0.8 respectively and summing the multiplication results, and then store the updated SOC 5.8% matching with the unit hour 13:00 within the hourly remaining battery capacity information for one day.

If determining to calculate the remaining operating time of the battery in operation 804, the application processor 210 searches the hourly remaining battery capacity information for one day and sums each reduced ratio from a current time to a specific future time in operation 805. If the sum value coincides with a present remaining battery capacity in operation 806, the application processor 210 predicts the specific future time as the remaining operating time of the battery in operation 807. For example, as illustrated in FIG. 12, assuming that the current time is 12:00, the application processor 210 sums each reduced ratio from 12:00 to 17:00. If the sum value (SUM) (30.0=4.5+5.0+4.5+5.0+4.5+6.0) coincides with a remaining battery capacity SOC 30% detected at the current time 12:00, or belongs to a tolerance range (e.g., ±5%) of the remaining battery capacity SOC 30%, the application processor 210 predicts that the remaining operating time of the battery will be 7 hours (e.g., up to 17:00).

In operation 808, the application processor 210 displays the predicted remaining operating time of the battery through a display screen. For example, if the remaining operating time of the battery is up to 17:00, as illustrated in FIG. 13, the application processor 210 may display 1 hour and 30 minutes after which it is predicted that the battery will be fully discharged, as the remaining operating time of the battery. As an alternative, the application processor 210 may display a time (e.g., 18:00) at which it is predicted that the battery will be discharged. The remaining operating time of the battery may be displayed together with any one or more of the current time, present remaining battery capacity information, and the reduced ratio per unit hour of the remaining battery capacity.

In operation 809, the application processor 210 performs operations requested by a user.

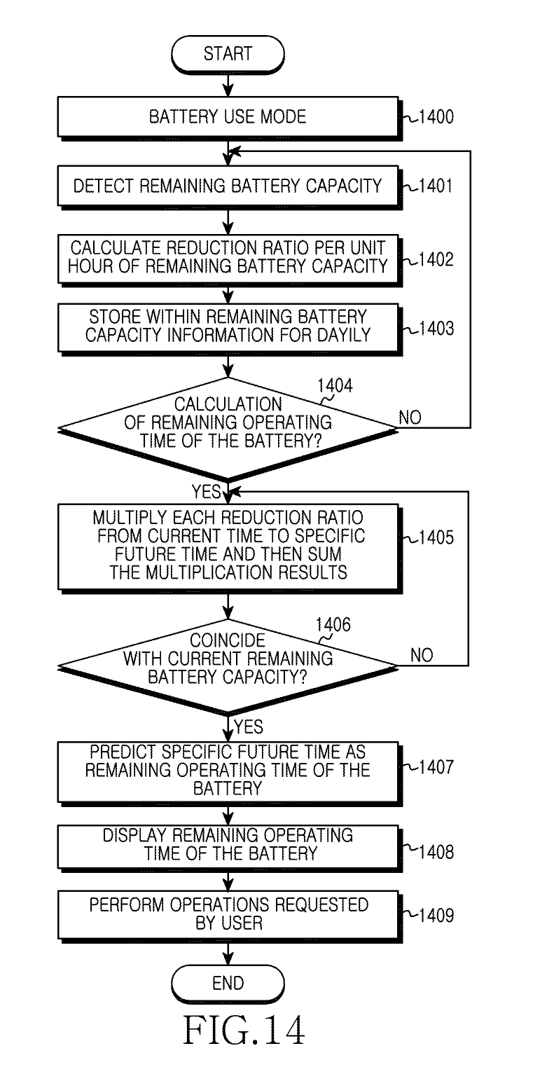

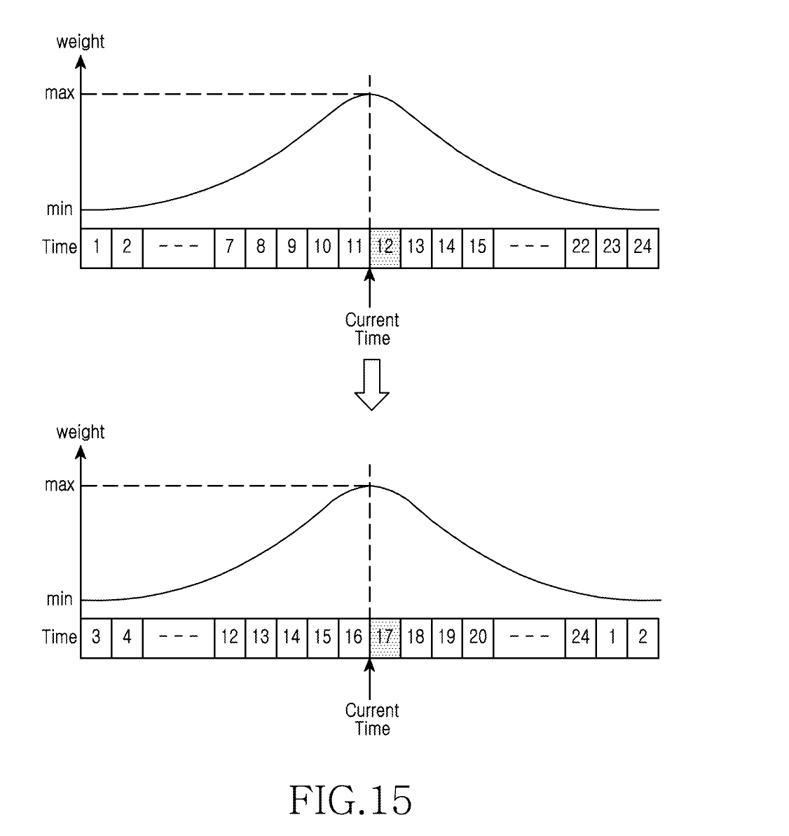

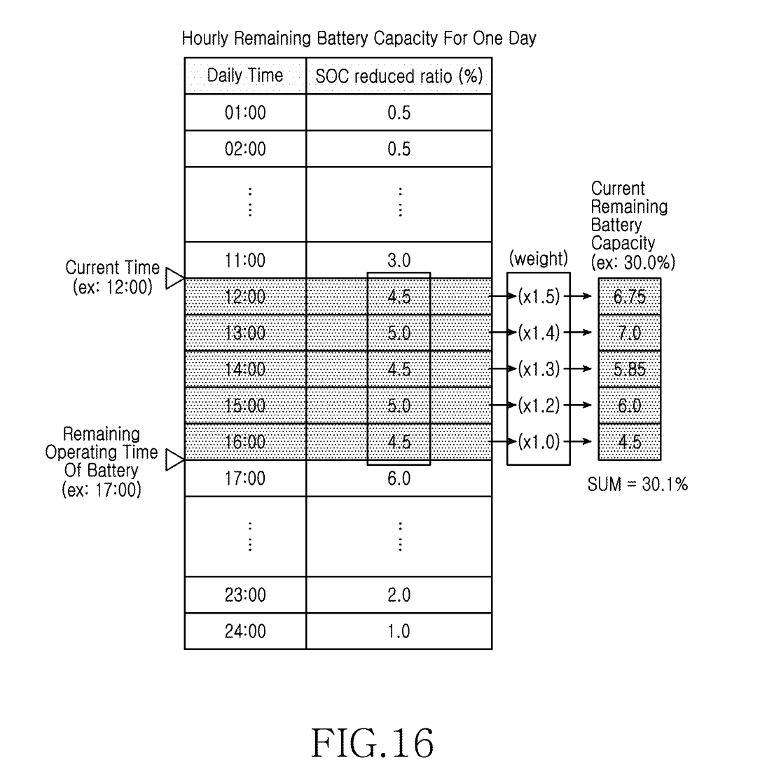

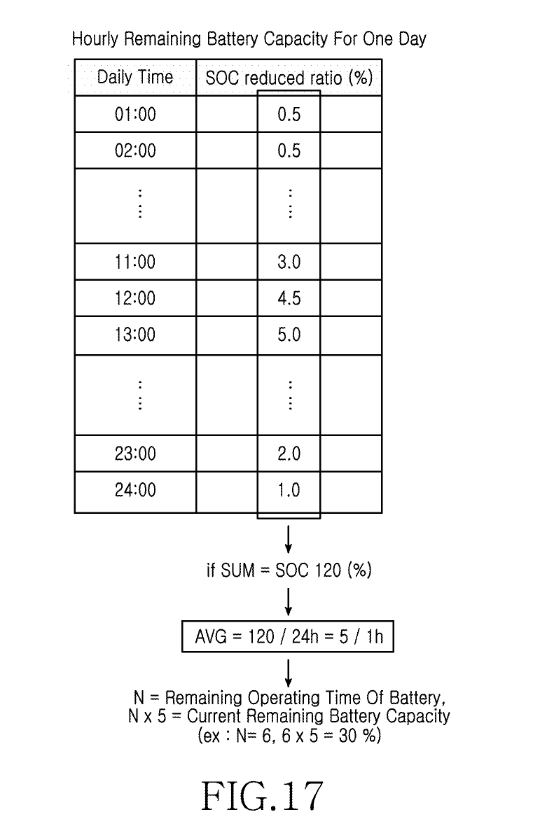

FIG. 14 is a flowchart illustrating an operation of a method for managing power of an electronic device in accordance to an embodiment of the present disclosure. FIG. 15 is a diagram illustrating applying a weight according to an embodiment of the present disclosure. FIG. 16 is a diagram illustrating predicting a remaining operating time of a battery according to an embodiment of the present disclosure. FIG. 17 is a diagram illustrating predicting a remaining operating time of a battery according to an embodiment of the present disclosure.

Referring to FIG. 14, a present power mode is a battery use mode in operation 1400. In operation 1401, the application processor 210 controls the battery gauge 300 to detect a remaining battery capacity at a certain frequency for a certain duration. For example, the application processor 210 may control the battery gauge to detect remaining battery capacity at a frequency of every hour for a period of 24 hours.

In operation 1402, the application processor 210 calculates a reduced ratio per unit hour of the remaining battery capacity, by comparing a voltage value detected by the battery gauge 300 with SOC information of the memory 303, searching an SOC % value of a current time, and calculating a difference value between the searched SOC % value and an SOC % value already searched at an earlier unit hour. For example, if an SOC % value of 14:00 is less than an SOC % value of 13:00 by 6%, the application processor 210 may calculate an SOC 6% as a reduced ratio of the remaining battery capacity which is reduced during 1 hour from 13:00 to 14:00.

In operation 1403, the application processor 210 stores the calculated reduced ratio SOC 6% of the remaining battery capacity, within the hourly remaining battery capacity information for one day. For example, as aforementioned with reference to FIG. 9, assuming that an SOC 5% matching with a unit hour 13:00 has been already stored within the hourly remaining battery capacity information for one day, the application processor 210 may update the SOC 5% into the newly calculated SOC 6% value and store the newly calculated SOC 6% value or, as aforementioned with reference to FIG. 10, the application processor 210 may update the SOC 5% into an average value SOC 5.5% of a sum of the SOC 5% and the SOC 6% and store the SOC 5.5%. Further, as aforementioned with reference to FIG. 11, the application processor 210 may update the SOC 5% into an SOC 5.8% value by multiplying the SOC 5% by 0.2 and multiplying the SOC 6% by 0.8 respectively and summing the multiplication results, and then store the updated SOC 5.8%.

If determining to calculate the remaining operating time of the battery in operation 1404, the application processor 210 searches the hourly remaining battery capacity information for one day, and multiplies each reduced ratio from a current time to a specific future time by a different weight and sums the multiplication results in operation 1405. If the sum value coincides with a present remaining battery capacity in operation 1406, the application processor 210 predicts the specific future time as the remaining operating time of the battery in operation 1407. For example, as illustrated in FIG. 15, the weight has a maximum value on a basis of a current time, and may apply a symmetric graph in which the weight gradually decreases as time goes away from the current time.

For example, as illustrated in FIG. 16, assuming that the current time is 12:00, the application processor 210 multiplies each reduced ratio from 12:00 to 16:00 by a different weight and then sums the multiplication results. If the sum value (SUM) (30.1=(4.5×1.5)+(5.0×1.4)+(4.5×1.3)+(5.0×1.2)+(4.5×1.0)) coincides with a remaining battery capacity SOC 30% detected at the current time 12:00, or belongs to a tolerance range (e.g., ±5%) of the remaining battery capacity SOC 30%, the application processor 210 predicts that the remaining operating time of the battery will be up to 16:00.

In operation 1408, the application processor 210 displays the predicted remaining operating time of the battery through a display screen. For example, if the remaining operating time of the battery is up to 16:00, the application processor 210 may display 17:00 at which time it is predicted that a battery will be fully discharged. The remaining operating time of the battery may be displayed together with any one or more of the current time, present remaining battery capacity information, and the reduced ratio per unit hour of the remaining battery capacity.

In operation 1409, the application processor 210 performs operations requested by a user.

The maximum value and minimum value of the weight which is applied to more accurately predict the remaining operating time of the battery may be changed into arbitrary values by user selection and further, may be also changed into arbitrary values based on the hourly remaining battery capacity information for one day. For example, the application processor 210 may not assign the weight to a unit hour at which the reduced ratio of the remaining battery capacity is extremely low and further, the application processor 210 may also apply a dynamic weight scheme of, when a reduced ratio of a remaining battery capacity of a current time is high, decreasing a range of application of the weight instead of increasing the maximum value of the weight and, inversely, when the reduced ratio of the remaining battery capacity of the current time is low, increasing the range of application of the weight instead of decreasing the maximum value of the weight.

Further, the application processor 210 may, for example, as illustrated in FIG. 17, calculate an average value of respective reduced ratios per unit hour of a remaining battery capacity which are stored within the hourly remaining battery capacity information for one day. For example, the application processor 210 may sum all of respective reduced ratios per unit hour of the remaining battery capacity of 24 hours and divide the summed result by 24 hours, thereby calculating an average value of reduced ratios per 1 hour, and calculating a remaining operating time of the battery based on the calculated average value. Assuming that a present remaining battery capacity is 30% and the average value of reduced ratios per 1 hour is 5%, the application processor 210 may calculate a remaining operating time of the battery (N) as 6 hours. Assuming that a current time is 12:00, the application processor 210 may predict that the remaining operating time of the battery will be up to 17:00 after 6 hours. Further, the application processor 210 may multiply the calculated average value by the weight per hour described earlier with reference to FIG. 16, and predict the remaining operating time of the battery.

The application processor 210 may display a message of at least any one of discharge, charge, or power saving in accordance with the remaining battery capacity, and may variably control a display time point of the message based on the reduced ratio per unit hour of the remaining battery capacity. For example, if a present remaining battery capacity is less than a preset reference remaining battery capacity, the application processor 210 may display a warning message showing any one or more of discharge, charge, or power saving.

Further, although the present remaining battery capacity is higher than the preset reference remaining battery capacity, if a remaining battery capacity reduced ratio after a current time is suddenly increased with reference to the hourly remaining battery capacity information for one day, the application processor 210 may control the display time point of the warning message to be faster. Inversely, although the present remaining battery capacity is lower than the preset reference remaining battery capacity, if the remaining battery capacity reduced ratio after the current time is extremely low with reference to the hourly remaining battery capacity information for one day, the application processor 210 may control the display time point of the warning message to be somewhat slow.

According to various embodiments of the present disclosure, an electronic device such as a smart phone, a tablet PC or the like reflects unique patterns of a user who variously uses the electronic device and accurately calculates a remaining operating time of the battery, thereby being able to improve the accuracy of information regarding the remaining operating time of the battery that the electronic device provides to the user. Also, the electronic device suitably controls the display time point of the warning message such as discharge, charge, power saving and the like, thereby being able to optimize the display time point of the warning message that the electronic device provides to the user.

Methods according to various embodiments stated in the claims and/or specification of the present disclosure may be implemented in a form of hardware, software, or a combination of hardware and software. If the methods are implemented in software, a computer-readable storage medium storing one or more programs (i.e., software modules) may be provided. The one or more programs stored in the computer-readable storage medium are configured to be executed by one or more processors 120 within an electronic device. The one or more programs include instructions for enabling the electronic device to execute the methods according to the various embodiments stated in the claims and/or specification of the various embodiments of the present disclosure.

These programs (i.e., software modules or software) may be stored in a Random Access Memory (RAM), a nonvolatile memory including a flash memory, a Read Only Memory (ROM), an Electrically Erasable Programmable ROM (EEPROM), a magnetic disk storage device, a Compact Disk ROM (CD-ROM), a Digital Versatile Disk (DVD) or an optical storage device of other form, and a magnetic cassette. Or, the programs may be stored in a memory constructed by a combination of some or all of them. Also, each constructed memory may be included in plural.

Also, the programs may be stored in an attachable storage device accessible through a communication network such as the Internet, an intranet, a Local Area Network (LAN), a Wireless LAN (WLAN) and a Storage Area Network (SAN) or a communication network constructed by a combination of them. This storage device may access a device performing an embodiment of the present disclosure through an external port. Also, a separate storage device on the communication network may access a device performing an embodiment of the present disclosure.

In the aforementioned various embodiments of the present disclosure, constituent elements of the disclosure have been expressed using singular numbers or plural numbers in accordance with the various described embodiments. But, this is merely for convenience of description. That is, the expression of a singular number or a plural number is suitably selected for a proposed situation for convenience of description, and the various embodiments of the present disclosure are not limited to singular or plural constituent elements. For example, the constituent element expressed with a plural number may be constructed in the singular, or the constituent element expressed as singular may be constructed in plural number.

While the present disclosure has been shown and described with reference to various embodiments thereof, it will be understood by those skilled in the art that various changes in form and details may be made therein without departing from the spirit and scope of the present disclosure as defined by the appended claims and their equivalents.

What is claimed is:

1. An operation method of an electronic device, the method comprising:
detecting a remaining battery capacity;
calculating and storing a reduced ratio per unit time of the remaining battery capacity; and
based on the reduced ratio, predicting a remaining operating time of the battery.

2. The method of claim 1, wherein the detecting of the remaining battery capacity is performed at a preset frequency, and
the preset frequency is set as an arbitrary time interval by a user selection or occurrence of an event corresponding to the remaining battery capacity.

3. The method of claim 1, wherein the unit time is one hour.

4. The method of claim 3, wherein the storing of the reduced ratio per unit hour comprises:
calculating the reduced ratio per unit hour of the remaining battery capacity; and
storing the calculated reduced ratio by each unit hour as hourly remaining battery capacity information for one day.

5. The method of claim 4, wherein the hourly remaining battery capacity information for one day comprises at least one of a currently calculated reduced ratio, an average value of a previously stored reduced ratio and the currently calculated reduced ratio, or a value determined by multiplying the previously stored reduced ratio by a 1^{st} weight (M) and the currently calculated reduced ratio by a 2^{nd} weight (N, N>M, N+M=1) respectively and a sum of the multiplication results.

6. The method of claim 4, further comprising the operation of storing the hourly remaining battery capacity information for one day, by the unit of each date within hourly remaining battery capacity information for one week or hourly remaining battery capacity information for one month.

7. The method of claim 1, wherein the predicting of the remaining operating time of the battery comprises:
summing each reduced ratio from a current time to a specific future time; and
if the summing result coincides with a present remaining battery capacity within a tolerance range, predicting the specific future time as the remaining operating time of the battery.

8. The method of claim 1, wherein the predicting of the remaining operating time of the battery comprises:
multiplying each reduced ratio from a current time to a specific future time by a weight;
summing the multiplication results; and,
if the summing result coincides with a present remaining battery capacity within a tolerance range, predicting the specific future time as the remaining operating time of the battery.

9. The method of claim 8, wherein the weight has a range of a maximum value to a minimum value,
wherein a reduced ratio of the current time is multiplied by a weight of the maximum value, and
wherein a reduced ratio of the specific future time is multiplied by a weight of a value less than the maximum value.

10. The method of claim 1, wherein the predicting of the remaining operating time of the battery comprises:
multiplying a specific future time by an average value of the reduced ratios per unit hour; and
if the multiplication result coincides with a present remaining battery capacity within a tolerance range, predicting the specific future time as the remaining operating time of the battery.

11. The method of claim 9, wherein the maximum value and the minimum value of the weight are set as arbitrary values by user selection, or are set as arbitrary values based on the hourly remaining battery capacity information for one day.

12. The method of claim 1, further comprising displaying the predicted remaining operating time of the battery,
wherein the remaining operating time of the battery is displayed together with any one or more of a current time, a present remaining battery capacity, and the reduced ratio per unit hour of the remaining battery capacity.

13. The method of claim 1, further comprising displaying a message of at least any one of discharge, charge, and power saving in accordance with the remaining battery capacity,
wherein a display time point of the message is controlled based on the reduced ratio per unit hour of the remaining battery capacity.

14. An electronic device comprising:
a detection unit configured to detect a remaining battery capacity; and
a control unit configured to:
calculate and store a reduced ratio per unit time of the remaining battery capacity, and
based on the reduced ratio, to predict a remaining operating time of the battery.

15. The device of claim 14, wherein the detection unit is further configured to detect the remaining battery capacity at a preset frequency, and
the preset frequency is set as an arbitrary time interval by a user selection or occurrence of an event corresponding to the remaining battery capacity.

16. The device of claim 14, wherein the unit time is one hour.

17. The device of claim 14, wherein the control unit is further configured to:
calculate the reduced ratio per unit hour of the remaining battery capacity; and
store the calculated reduced ratio by each unit hour as hourly remaining battery capacity information for one day.

18. The device of claim 17, wherein the hourly remaining battery capacity information for one day comprises at least one of a currently calculated reduced ratio, an average value of a previously stored reduced ratio and the currently calculated reduced ratio, or a value determined by multiplying the previously stored reduced ratio by a 1^{st} weight (M) and the currently calculated reduced ratio by a 2^{nd} weight (N, N>M, N+M=1) respectively and a sum of the multiplication results.

19. The device of claim 17, wherein the control unit is further configured to store the hourly remaining battery capacity information for one day by the unit of each date within hourly remaining battery capacity information for one week or hourly remaining battery capacity information for one month.

20. The device of claim 14, wherein the control unit is further configured to:
sum each reduced ratio from a current time to a specific future time; and
if the summing result coincides with a present remaining battery capacity within a tolerance range, predict the specific future time as the remaining operating time of the battery.

21. The device of claim 14, wherein the control unit is further configured to:
multiply each reduced ratio from a current time to a specific future time by a weight;
sum the multiplication results; and
if the summing result coincides with a present remaining battery capacity within a tolerance range, predict the specific future time as the remaining operating time of the battery.

22. The device of claim 20, wherein the weight has a range of a maximum value to a minimum value, and wherein the control unit multiplies a reduced ratio of the current time by a weight of the maximum value, and multiplies a reduced ratio of the specific future time by a weight of a value less than the maximum value.

23. The device of claim 22, wherein the maximum value and the minimum value of the weight are set as arbitrary values by a user selection, or are set as arbitrary values based on the hourly remaining battery capacity information for one day.

24. The device of claim 14, wherein the control unit is further configured to:
multiply a specific future time by an average value of the reduced ratios per unit hour; and
if the multiplication result coincides with a present remaining battery capacity within a tolerance range, predict the specific future time as the remaining operating time of the battery.

25. The device of claim 14, wherein the control unit is further configured to display the predicted remaining operating time of the battery, the remaining operating time of the battery being displayed together with any one or more of a current time, a present remaining battery capacity, and the reduced ratio per unit hour of the remaining battery capacity.

26. The device of claim 14, wherein the control unit is further configured to display a message of at least any one of discharge, charge, and power saving in accordance with the remaining battery capacity, and to control a display time point of the message based on the reduced ratio per unit hour of the remaining battery capacity.

27. A computer-readable storage medium storing a program for carrying out a method comprising:
detecting a remaining battery capacity;
calculating and storing a reduced ratio per unit time of the remaining battery capacity; and
based on the reduced ratio, predicting a remaining operating time of the battery.
